(19) United States
(12) Patent Application Publication
(10) Pub. No.: US 2017/0053878 A1
(43) Pub. Date: Feb. 23, 2017

(54) PRINTED WIRING BOARD AND SEMICONDUCTOR PACKAGE

(71) Applicant: IBIDEN CO., LTD., Ogaki (JP)

(72) Inventors: Kazuki KAJIHARA, Ogaki (JP); Takema ADACHI, Ogaki (JP); Teruyuki ISHIHARA, Ogaki (JP); Kosuke IKEDA, Ogaki (JP)

(73) Assignee: IBIDEN CO., LTD., Ogaki (JP)

(21) Appl. No.: 15/239,865

(22) Filed: Aug. 18, 2016

(30) Foreign Application Priority Data
Aug. 18, 2015 (JP) 2015-161191

(51) Int. Cl. H01L 23/00; H01L 21/48; H01L 25/10; H01L 23/498; H01L 23/31

(52) U.S. Cl. CPC H01L 23/562; H01L 23/49822; H01L 23/49838; H01L 23/49827; H01L 23/49894; H01L 23/3142; H01L 25/105; H01L 21/4857; H01L 21/486; H01L 21/4853; H01L 2225/1058

(57) ABSTRACT

A printed wiring board includes a build-up layer including insulating and conductor layers, pads formed on surface of the build-up layer and including first pads to connect an electronic component and second pads to connect an external wiring board onto the surface of the build-up layer, a mold resin layer formed on the surface of the build-up layer such that the mold layer is covering the surface of the build-up layer and has a cavity exposing the first pads and openings exposing the second pads, and conductor posts formed in the openings and including plating material such that the posts are connected to the second pads. The plating material of the posts includes electroless plating layer and electrolytic plating layer, and the posts are formed such that each post has an end surface exposed from surface of the mold layer on the opposite side with respect to the second pads.

### CROSS-REFERENCE TO RELATED APPLICATIONS

The present application is based upon and claims the benefit of priority to Japanese Patent Application No. 2015-161191, filed Aug. 18, 2015, the entire contents of which are incorporated herein by reference.

### BACKGROUND OF THE INVENTION

Field of the Invention

The present invention relates to a printed wiring board having a cavity, and relates to a semiconductor package that includes such a printed wiring board.

### DESCRIPTION OF BACKGROUND ART

U.S. Patent Application Publication No. 2010/0289134 describes an electronic component package. In the electronic component package of Patent Document 1, a pad for external connection is formed in a peripheral part of a lower package in which an electronic component is mounted, and a connection terminal for lamination for connecting to an upper package is formed on the pad for external connection. An reinforcing sealing layer that is formed surrounding the connection terminal for lamination is lower than a height of the connection terminal for lamination, and the connection terminal for lamination is exposed from a surface of the reinforcing sealing layer. The entire contents of this publication are incorporated herein by reference.

### SUMMARY OF THE INVENTION

According to one aspect of the present invention, a printed wiring board includes a build-up wiring layer including a resin insulating layer and a conductor layer, pads formed on a first surface of the build-up wiring layer and including first pads and second pads such that the first pads are positioned to connect an electronic component onto the first surface of the build-up wiring layer and the second pads are positioned to connect an external wiring board onto the first surface of the build-up wiring layer, a mold resin layer formed on the first surface of the build-up wiring layer such that the mold resin layer is covering the first surface of the build-up wiring layer and has a cavity portion exposing the first pads and opening portions exposing the second pads, respectively, and conductor posts formed in the opening portions of the mold resin layer respectively and including plating material such that the conductor posts are connected to the second pads, respectively. The plating material of the conductor posts includes an electroless plating layer and an electrolytic plating layer, and the conductor posts are formed such that each of the conductor posts has an end surface exposed from a surface of the mold resin layer on the opposite side with respect to the second pads.

According to another aspect of the present invention, a semiconductor package includes a printed wiring board, a first semiconductor element mounted on the printed wiring board, and an external wiring board mounted on the printed wiring board. The printed wiring board includes a build-up wiring layer including a resin insulating layer and a conductor layer, pads formed on a first surface of the build-up wiring layer and including first pads and second pads such that the first pads are positioned to connect the electronic component onto the first surface of the build-up wiring layer and the second pads are positioned to connect the external wiring board onto the surface of the build-up wiring layer, a mold resin layer formed on the first surface of the build-up wiring layer such that the mold resin layer is covering the first surface of the build-up wiring layer and has a cavity portion exposing the first pads and opening portions exposing the second pads, respectively, and conductor posts formed in the opening portions of the mold resin layer respectively and including plating material such that the conductor posts are connected to the second pads, respectively, the plating material of the conductor posts includes an electroless plating layer and an electrolytic plating layer, the conductor posts are formed such that each of the conductor posts has an end surface exposed from a surface of the mold resin layer on the opposite side with respect to the second pads and that each of the conductor posts has a tapered form decreasing a diameter toward a respective one of the second pads, and the external wiring board has bumps positioned to connect to the conductor posts respectively such that the external wiring board is electrically connected to the build-up wiring layer of the printed wiring board.

According to yet another aspect of the present invention, a method for manufacturing a printed wiring board includes forming, on a surface of a resin insulating layer, pads including first pads and second pads such that the first pads are positioned to connect an electronic component onto the surface of the resin insulating layer and the second pads are positioned to connect an external wiring board onto the surface of the resin insulating layer, forming, on the first pads, a dummy member having a shape corresponding to a cavity portion, such that the dummy member covers the first pads, applying mold resin onto the surface of the resin insulating layer such that the mold resin covers the surface of the resin insulating layer and the dummy member formed on the first pads, polishing the mold resin applied onto the surface of the resin insulating layer such that a surface of the dummy member is exposed, and removing the dummy member from the resin insulating layer such that a mold resin layer having the cavity portion is formed on the surface of the resin insulating layer to expose the first pads in the cavity portion of the mold resin layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a printed wiring board according to an embodiment of the present invention;

FIG. 2A illustrates an example of a conductor post;

FIG. 2B illustrates another example of a conductor post;

FIG. 3 is a plan view of the printed wiring board of the embodiment of the present invention;

FIG. 4 is a cross-sectional view of a printed wiring board according to another embodiment of the present invention;

FIG. 5A is a cross-sectional view of a semiconductor package of the embodiment of the present invention;

FIG. 5B is a cross-sectional view illustrating an example in which a sealing resin is filled in the semiconductor package illustrated in FIG. 5A;

FIG. 5C is a cross-sectional view illustrating a state in which a second semiconductor element is mounted on the semiconductor package illustrated in FIG. 5B;

FIG. 6A illustrates a method for manufacturing the printed wiring board of the embodiment of the present invention;

FIG. 6B illustrates the method for manufacturing the printed wiring board of the embodiment of the present invention;

FIG. 6C illustrates the method for manufacturing the printed wiring board of the embodiment of the present invention;

FIG. 6D illustrates the method for manufacturing the printed wiring board of the embodiment of the present invention;

FIG. 6E illustrates the method for manufacturing the printed wiring board of the embodiment of the present invention;

FIG. 6F illustrates the method for manufacturing the printed wiring board of the embodiment of the present invention;

FIG. 6G illustrates the method for manufacturing the printed wiring board of the embodiment of the present invention;

FIG. 6H illustrates the method for manufacturing the printed wiring board of the embodiment of the present invention;

FIG. 6I illustrates the method for manufacturing the printed wiring board of the embodiment of the present invention;

FIG. 6J illustrates the method for manufacturing the printed wiring board of the embodiment of the present invention;

FIG. 6K illustrates the method for manufacturing the printed wiring board of the embodiment of the present invention;

FIG. 6L illustrates the method for manufacturing the printed wiring board of the embodiment of the present invention;

FIG. 6M illustrates the method for manufacturing the printed wiring board of the embodiment of the present invention;

FIG. 6N illustrates the method for manufacturing the printed wiring board of the embodiment of the present invention;

FIG. 7A is a cross-sectional view of a printed wiring board of another embodiment of the present invention;

FIG. 7B illustrates a method for manufacturing the printed wiring board of the other embodiment of the present invention; and

FIG. 7C is a cross-sectional view illustrating a state in which an electronic component is mounted on the printed wiring board of the other embodiment illustrated in FIG. 7A.

### DETAILED DESCRIPTION OF THE EMBODIMENTS

The embodiments will now be described with reference to the accompanying drawings, wherein like reference numerals designate corresponding or identical elements throughout the various drawings.

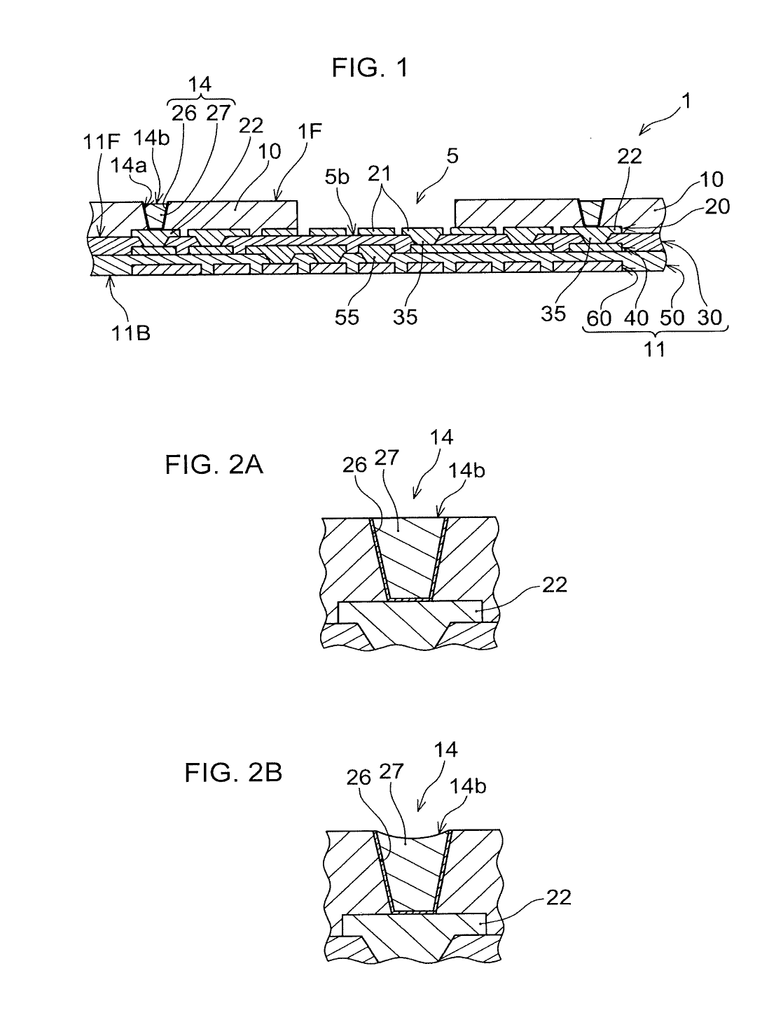

FIG. 1 describes a cross section of a printed wiring board 1 of an embodiment. The printed wiring board 1 includes a build-up wiring layer 11 that has a first surface (11F) and a second surface (11B) that is on an opposite side of the first surface (11F), a mold resin layer 10 that is formed on the first surface (11F) of the build-up wiring layer 11, and a cavity (recess) 5 that exposes a first pad 21 that is connected to an electronic component. The mold resin layer 10 has an opening (14a) that exposes a portion of a second pad 22 that is connected to an external wiring board. A conductor post 14 is formed from a plating layer in the opening (14a) of the mold resin layer 10 so as to be in contact with the second pad 22.

The conductor post 14 is formed from an electroless plating film 26 and an electrolytic plating film 27 and is a columnar conductor that penetrates the mold resin layer 10. An end surface (14b) of the conductor post 14 on an opposite side of the second pad 22 side is exposed on a surface of the mold resin layer 10 (first surface (1F) of the printed wiring board 1). The opening (14a) is formed, for example, by irradiating a laser beam to the mold resin layer 10 from the surface of the mold resin layer 10. Power of the laser beam is likely to gradually weaken from the surface side of the mold resin layer 10 toward the second pad 22 side. Therefore, as illustrated in FIG. 1, the opening (14a) and the conductor post 14 that is formed from the plating layer in the opening (14a) each have a tapered shape that is gradually reduced in diameter toward the second pad 22.

In the present embodiment, as illustrated in FIG. 1, the conductor post 14 is formed by filling a conductor formed from the electroless plating film 26 and the electrolytic plating film 27 in the opening (14a). Preferably, the electroless plating film 26 is a copper plating film. The electroless plating film 26 is preferably formed to have a thickness of 0.05 μm or more and 1 μm or less. The electroless plating film 26, for example, may also be formed from a metal other than copper, such as nickel. Further, when necessary, a thin metal (such as copper) film may be formed using a sputtering method. The electrolytic plating film 27 is preferably a copper plating film. It is also possible that the electrolytic plating film 27 is a plating film formed from other metal materials such as nickel.

According to the present embodiment, the conductor post 14 is formed from the plating layer by performing plating processing using the second pad 22 of a conductor layer 20 and the electroless plating film 26 on the mold resin layer 10 as a seed layer. The electroless plating film 26 is also formed on an inner wall of the opening (14a). Since the seed layer also exists on the inner wall surface of the opening (14a), it is likely that the opening (14a) is surely filled with the electrolytic plating film 27 (and the electroless plating film 26). The conductor post 14 is likely to have a high mechanical strength. Further, connection between the conductor layer 20 and the conductor post 14 is bonding between metals of the same kind and thus strength of the bonding is likely to be high. A stress due to a difference in thermal expansion coefficient between the conductor post 14 and the conductor layer 20 is also likely to be small. A long-term reliability of electrical connection via the conductor post 14 is likely to be high.

According to the present embodiment, the electroless plating film 26 is formed over the entire inner wall of the opening (14a). Therefore, a current density is uniform, and the filling with the electrolytic copper plating can be reliably performed at a relatively uniform density. It is likely that reliability of the connection of the conductor post 14 is improved. As will be described later, before the plating processing, preferably, the inner wall surface of the opening (14a) is subjected to a roughening treatment such as a desmear treatment. A contact area between the electroless plating film 26 and the wall surface of the opening (14a) is increased and thus adhesion between the conductor post 14 and the mold resin layer 10 is improved. When an external wiring board is connected to the printed wiring board 1 via the second pad 22, thermal distortion due to a difference in thermal expansion between the two occurs, and a shear stress or a tensile stress is likely to act on the conductor post 14. According to the present embodiment, the conductor post 14 is reliably fixed. Peeling of the mold resin layer 10 and the conductor post 14 can be prevented. Reliability of the printed wiring board 1 can be improved.

In FIG. 1, the end surface (14b) of the conductor post 14 is recessed from the surface of the mold resin layer 10. In the connection to the external wiring board via the conductor post 14, a portion of the mold resin layer 10 can become a wall for a bonding material such as solder. An electrical short circuit state due to contact between adjacent electrodes or the like and the bonding material can be prevented.

FIGS. 2A and 2B illustrate other examples of the conductor post 14. FIG. 2A illustrates an example in which the end surface (14b) of the conductor post 14 is formed to be substantially flush with the surface of the mold resin layer 10. For example, when a pad of the external wiring board and the conductor post 14 are connected by copper-copper bonding or the like without using a bonding material or the like, even in the example illustrated in FIG. 2A, a problem such as a short circuit is unlikely to occur. As in the example illustrated in FIG. 2B, it is also possible that the end surface (14b) of the conductor post 14 is a concave curved surface that is concaved toward inside of the conductor post 14. When a bonding material such as solder is used for the connection to the external wiring board, it is likely that a risk that a short circuit may occur is reduced as compared to the example of FIG. 2A. Further, an area of the end surface (14b) is larger as compared to the example of FIG. 2A. Such a shape can be formed by subjecting the electrolytic plating film 27 that forms the conductor post 14 to an etching process, in particular, an over etching process. The external wiring board can be more firmly connected.

The end surface (14b) and a side surface of the conductor post 14 may be different in surface roughness. In some cases, it is preferable that the roughness of the end surface (14b) of the conductor post 14 be lower than the roughness of the side surface. In the end surface (14b), a contact area is ensured by sufficient flow of solder or the like into not-too-deep recessed portions of the rough surface. On the other hand, between the side surface of the conductor post 14 and the mold resin layer 10, it is likely that a stronger anchor effect is achieved and adhesion strength is increased. The surface roughness of the end surface (14b) of the conductor post 14 is, for example, 0.1 μm or more and 1.0 μm or less, and preferably 0.2 μm or more and 0.5 μm or less in arithmetic average roughness. Further, the surface roughness of the side surface of the conductor post 14 is, for example, 1.0 μm or more and 10 μm or less, and preferably 1.0 μm or more and 5 μm or less.

An electronic component that is mounted on the printed wiring board 1 is preferably accommodated in the cavity 5. The cavity 5 exposes the first pad 21 on a bottom surface (5b) and has an opening part on the first surface (1F) of the printed wiring board 1. For example, the electronic component can be connected to the printed wiring board 1 via the first pad 21.

Examples of the electronic component include a semiconductor element, a passive element (such as a capacitor, a resistor or an inductor), an interposer having a rewiring layer, a semiconductor element having a rewiring layer, a WLP (Wafer Level Package), and the like.

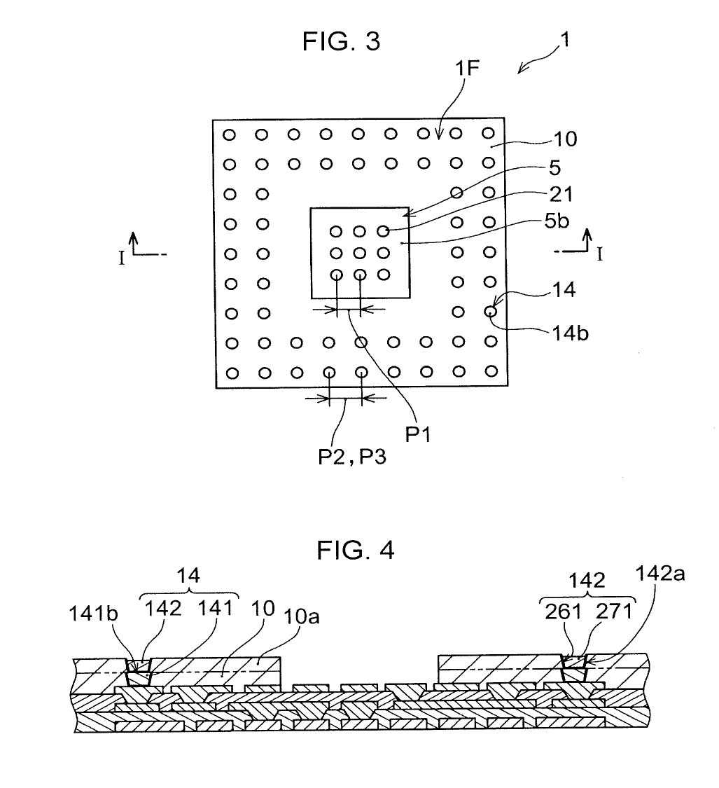

An example of a plan view of the printed wiring board 1 of the present embodiment is illustrated in FIG. 3. FIG. 3 illustrates the first surface (1F) side of the printed wiring board 1 of the present embodiment. A diagram describing a cross section at a position illustrated in FIG. 3 by a line I-I passing through a first pad 21 is FIG. 1. In FIG. 3, first pads 21 are formed substantially concentrated at a center of the printed wiring board 1. That is, in FIG. 3, the cavity 5, in which the first pads 21 are exposed on the bottom surface (5b), is formed at a substantially central position of the printed wiring board 1. This facilitates mounting an electronic component in the cavity 5. Further, it is also possible that multiple cavities 5 are provided at separate locations. As illustrated in FIG. 3, the end surface (14b) of the conductor post 14 is exposed on the surface of the mold resin layer 10 on an outer peripheral side of the cavity 5 of the printed wiring board 1.

In FIG. 3, for simplicity, only nine first pads 21 are illustrated. However, in practice, a much larger number of first pads 21 can be formed. It is also possible that multiple electronic components are accommodated in the cavity 5 and are respectively connected via the first pads 21 to a wiring layer of the printed wiring board 1. A position and a size of the cavity 5 and the number and positions of the first pads 21 can be suitably selected according to the number of electronic components mounted in the cavity 5 and positions of electrodes in the cavity 5. In the present embodiment, a distance (pitch) (P1) between adjacent first pads 21 is smaller than a distance (pitch) (P2) between adjacent second pads 22. In the present embodiment, a conductor post 14 is bonded to a second pad 22 such that center lines of the conductor post 14 and the second pad 22 overlap each other. Therefore, a distance (pitch) (P3) between adjacent conductor posts 14 is equal to the distance (pitch) (P2) between adjacent second pads 22. Therefore, as illustrated in FIG. 3, the distance (pitch) (P1) between adjacent first pads 21 is smaller than the distance (pitch) (P3) between adjacent conductor posts 14.

The positions of the conductor posts 14 are not limited to the positions illustrated in FIG. 3. An arbitrary number of conductor posts 14 may be formed at arbitrary positions depending on an external wiring board to be connected to the printed wiring board 1. For example, the first pads 21, the second pads 22 and the conductor posts 14 may be respectively formed in a lattice-like array or a zigzag array.

The printed wiring board of the present embodiment includes a build-up wiring layer. The build-up wiring layer is formed from alternately laminated resin insulating layers and conductor layers, the conductor layers each having a predetermined wiring pattern. In the printed wiring board 1 illustrated in FIG. 1, a resin insulating layer 30 is formed as an outermost layer on the first surface (11F) side of the build-up wiring layer 11. The conductor layer 20 is formed on the resin insulating layer 30. A second conductor layer 40 and a second resin insulating layer 50 are formed on an opposite side of the conductor layer 20 side of the resin insulating layer 30. A third conductor layer 60 is formed on an opposite side of the second conductor layer 40 side of the second resin insulating layer 50. The third conductor layer 60 is embedded in the second resin insulating layer 50. One side of the third conductor layer 60 is exposed from the second resin insulating layer 50. The conductor layer 20 and the second conductor layer 40 are connected to each other by a via conductor 35 that penetrates the resin insulating layer 30. The second conductor layer 40 and the third conductor layer 60 are connected to each other by a via conductor 55 that penetrates the resin insulating layer 50.

The resin insulating layer 30 and the second resin insulating layer 50 in the build-up wiring layer 11 are mainly formed from a resin material such as an epoxy resin. The resin material may be a prepreg material formed by impregnating a reinforcing material with an epoxy or another resin composition. The reinforcing material is not particularly limited. Preferably, glass fiber or the like is used as the reinforcing material. The resin material may contain 30% by mass or more and 90% by mass or less of an inorganic filler such as silica or alumina. The resin insulating layers are each formed to have a thickness of, for example, 5 μm or more and 30 μm or less.

The printed wiring board 1 has the mold resin layer 10 that is formed on the first surface (11F) of the build-up wiring layer 11. The cavity 5, in which the first pad 21 is exposed on the bottom surface, and the opening (14a) that exposes a portion of the second pad 22 are provided in the mold resin layer 10. A material of the mold resin layer 10 is not particularly limited as long as the material has a good insulating property. An example of the material is an epoxy resin. The material of the mold resin layer 10 may contain an inorganic filler that contains SiO₂ or the like. The amount of the inorganic filler contained in the material is, for example, 60% by mass or more and 95% by mass or less.

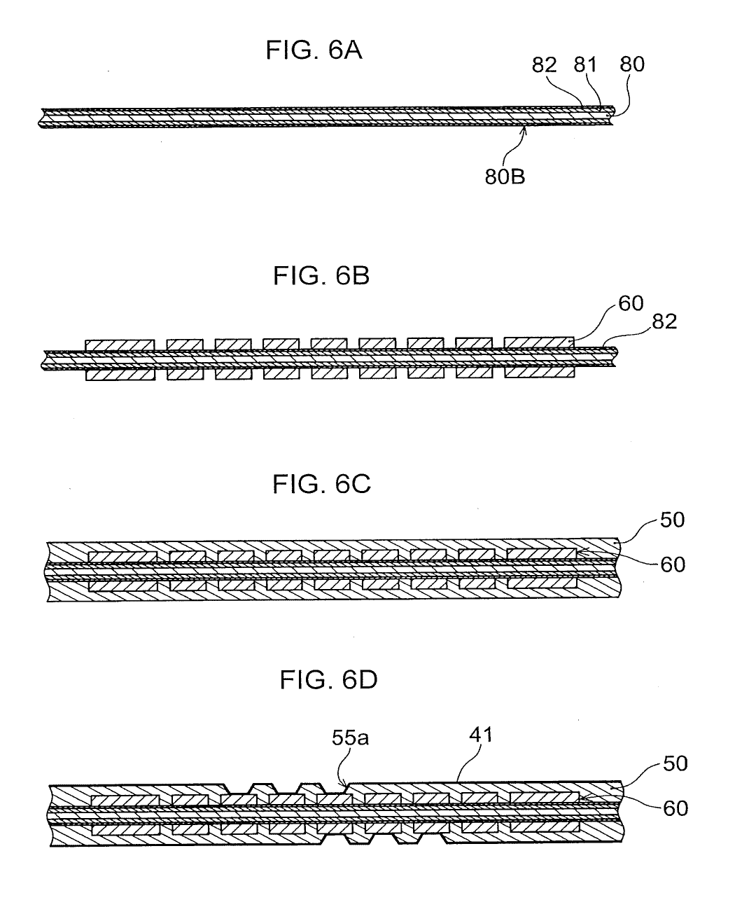

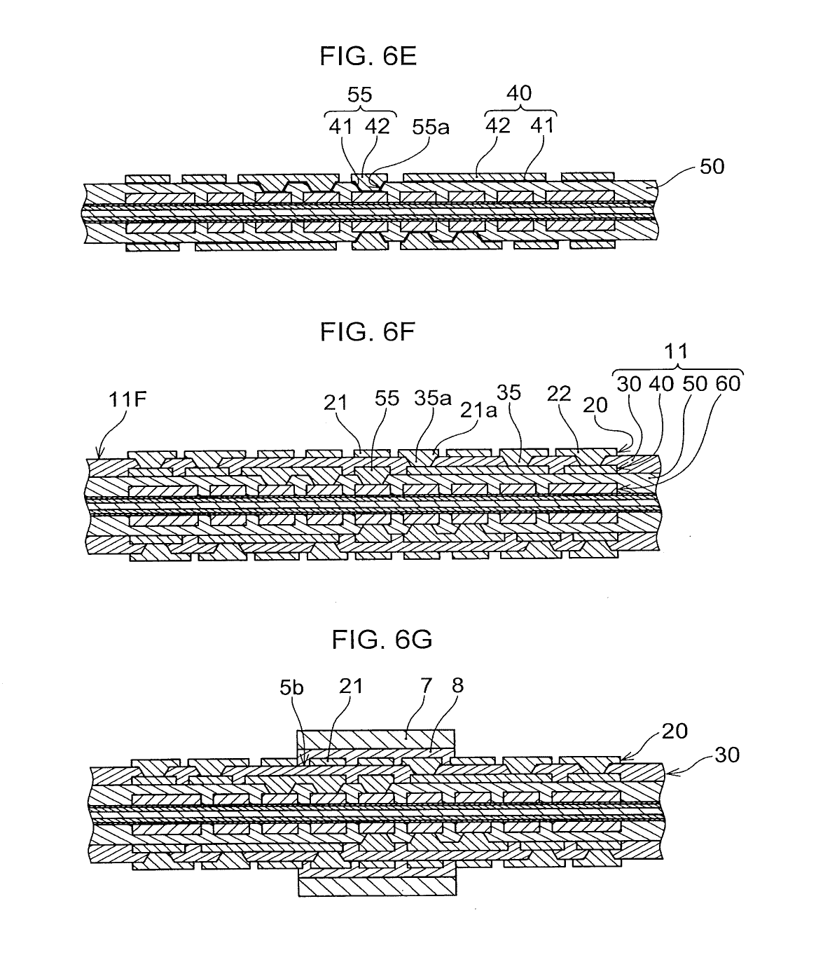

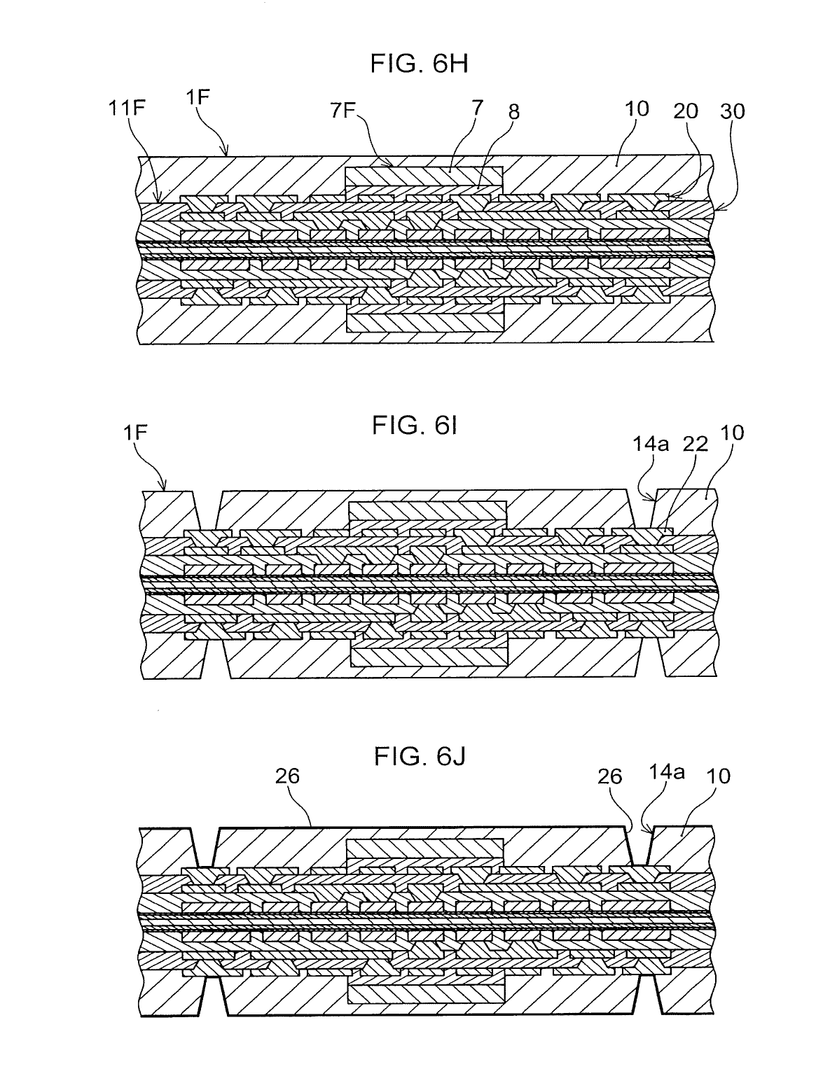

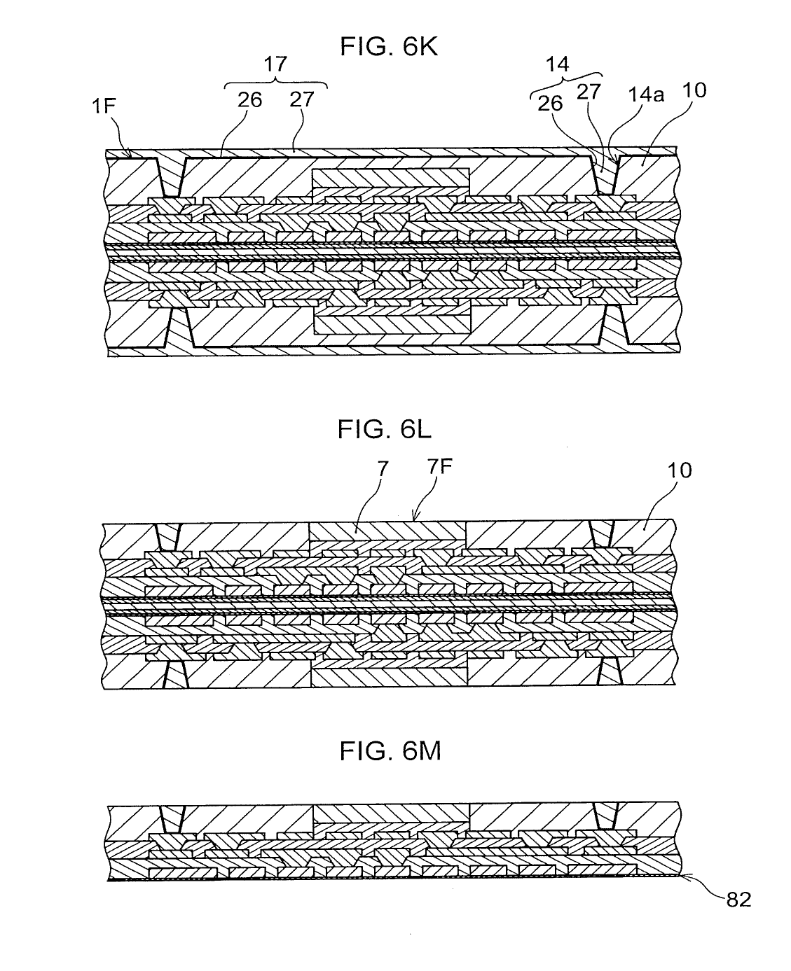

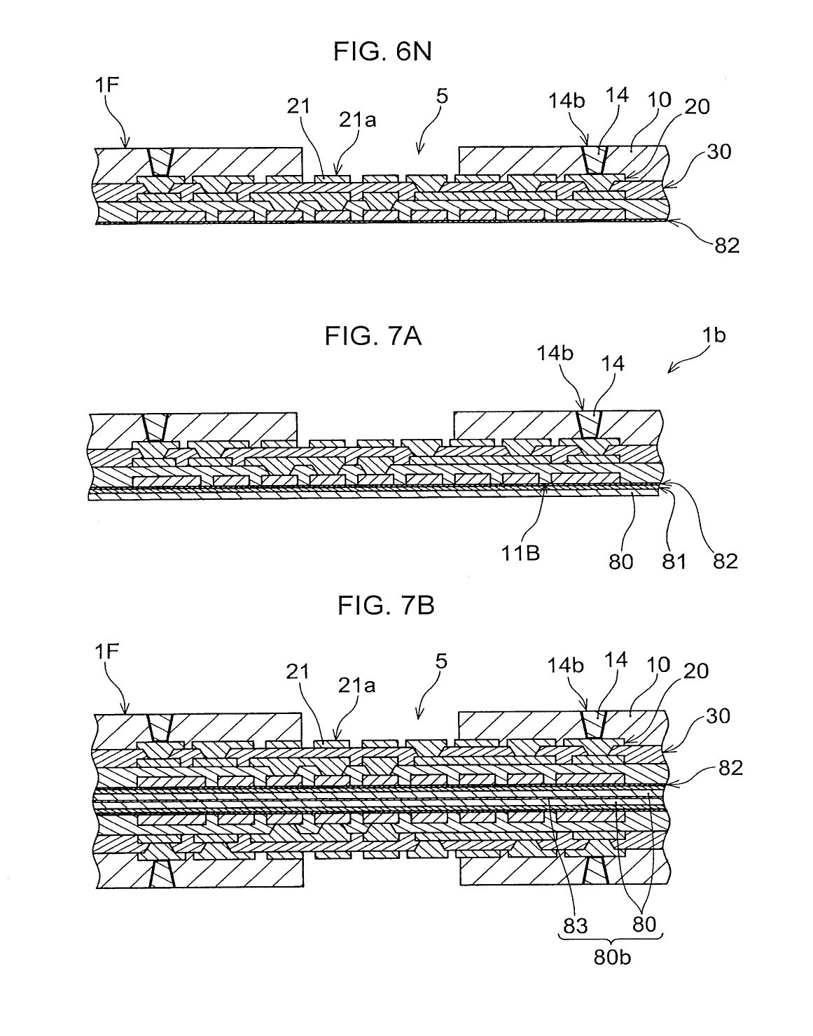

The mold resin layer 10 has a thickness of, for example, 50 μm or more and 150 μm or less. This thickness is substantially equal to a depth of the cavity 5. The depth of the cavity 5 refers to a distance from the first surface (1F) of the printed wiring board 1 to a surface of the first pad 21. This distance, for example, as will be described later, can be easily adjusted by changing a thickness of a dummy member 7 (see FIG. 6G) that is used when the mold resin layer 10 is formed. The depth of the cavity 5 can be arbitrarily selected depending on a thickness or the like of an electronic component to be accommodated in the cavity 5.

In the example illustrated in FIG. 3, the cavity 5 has a substantially square planar shape. Without being limited to this, the cavity 5 may also have other planar shapes such as a circular planar shape. The cavity 5 can be formed to have any planar shape depending on a shape or the like of an electronic component to be accommodated in the cavity 5.

The conductor post 14 has a height of 30 μm or more and 150 μm or less. The height of the conductor post 14 is set according to a thickness of the mold resin layer 10. That is, the height of the conductor post 14 can be set according to the depth of the cavity 5. The conductor post 14 may be formed in two stages. This example is illustrated in FIG. 4. A conductor post of a laminated structure may be preferred when a deep cavity 5 is formed. A second conductor post 142 is formed on an end surface (141b) of a first conductor post 141. After the first conductor post 141 is formed, an electroless plating film is formed on the end surface (141b). Using this electroless plating film as a seed layer, an electrolytic plating film of the second conductor post 142 is formed. Details of a method for manufacturing a conductor post of a laminated structure will be described later. Even when a conductor post 14 having a relatively high overall height is formed, the conductor posts (141, 142) can each have a height that is substantially half the desired height of the conductor post 14. It is likely that the opening (14a) for the formation of the first and second conductor posts (141, 142) is relatively evenly filled with the electrolytic plating film. It is likely that a conductor post 14 having a uniform density and less voids is formed. The conductor post 14 may have a laminated structure of two or more layers. The conductor post can be formed to have any height.

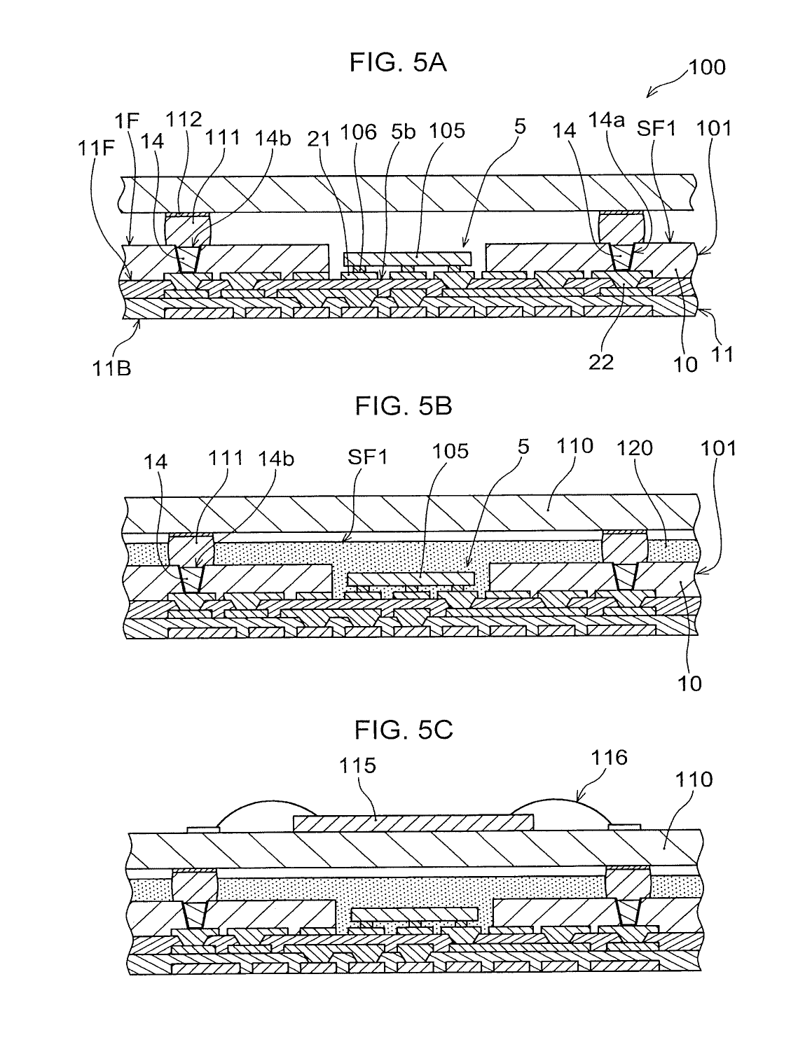

A semiconductor package can be formed using the printed wiring board of the present embodiment. FIG. 5A illustrates a semiconductor package 100 of the present embodiment.

The semiconductor package 100 includes a printed wiring board 101 and another wiring board 110. A first semiconductor element 105 is mounted on a surface (SF1) on one side of the printed wiring board 101. The wiring board 110 is mounted above the surface (SF1) on the one side of the printed wiring board 101. The printed wiring board 1 illustrated in FIG. 1 is preferably used as the printed wiring board 101. An example thereof is illustrated in FIG. 5A. Many of the components of the printed wiring board 101 illustrated in FIG. 5A are the same as in the printed wiring board 1 illustrated in FIG. 1, and such components are denoted using the same reference numeral symbols and detailed description thereof is omitted. The printed wiring board 101 is not limited to the printed wiring board 1 illustrated in FIG. 1, but may incorporate various modifications and variations with respect to the respective components as indicated in the above description of the printed wiring board 1.

As illustrated in FIG. 5A, similar to the printed wiring board 1 illustrated in FIG. 1, the printed wiring board 101 includes a build-up wiring layer 11 that has a first surface (11F) and a second surface (11B) that is on an opposite side of the first surface (11F), a mold resin layer 10 that is formed on the first surface (11F) of the build-up wiring layer 11, and a cavity 5 that exposes a first pad 21 that is connected to an electronic component. A conductor post 14 is formed from a plating layer in an opening (14a) of the mold resin layer 10 that exposes a portion of a second pad 22. The conductor post 14 has a tapered shape that is gradually reduced in diameter toward the second pad 22. An end surface (14b) of the conductor post 14 is exposed on a surface of the mold resin layer 10.

The first semiconductor element 105 is positioned in the cavity 5 of the printed wiring board 101. The first semiconductor element 105 has an electrode 106. The electrode 106 is connected to the first pad 21 that is exposed on a bottom surface (5b) of the cavity 5 of the printed wiring board 110. A method for the connection between the electrode 106 and the first pad 21 is not particularly limited. However, for example, an inter-metal junction between the two may be formed by applying heat, pressure and/or vibration. The electrode 106 and the first pad 21 may also be connected using a bonding member (not illustrated in the drawings) formed of a conductive material such as solder. In the example illustrated in FIG. 5A, one semiconductor element is accommodated in the cavity 5. However, it is also possible that multiple semiconductor elements are mounted on the printed wiring board 101. A type of a semiconductor element to be accommodated in the cavity 5 is not particularly limited. Preferably, an electronic component having a thickness that does not exceed the depth of the cavity 5 is mounted. When the number of semiconductor elements that can be mounted in the printed wiring board 1 increases, for example, the number of connecting parts for connecting to another wiring board such as the wiring board 110 is likely to decrease. It is possible that the reliability of the semiconductor package 100, or an electronic device in which the semiconductor package 100 is used, is improved.

As illustrated in FIG. 5A, the wiring board 110 has a bump 111 on a connection pad 112 on a surface on the printed wiring board 101 side. The wiring board 110 is connected to the conductor post 14 via the bump 111. In the printed wiring board 101, similar to the printed wiring board 1 illustrated in FIG. 1, the conductor post 14 is formed from an electroless plating film 26 and an electrolytic plating film 27, the electroless plating film 26 being formed over an entire inner wall of the opening (14a). The conductor post 14 is firmly directly bonded to the second pad 22. In the example illustrated in FIG. 5A, the end surface (14b) of the conductor post 14 of the printed wiring board 101 is recessed from the surface of the mold resin layer 10. A short circuit or the like is unlikely to occur in the connection between the bump 111 of the wiring board 110 and the conductor post 14. The wiring board 110 and the printed wiring board 101 are connected to each other with high reliability.

A structure and a material of the wiring board 110 are not particularly limited. The wiring board 110 may be a printed wiring board (for example, a coreless wiring board) that includes a resin insulating layer formed of a resin material and a conductor layer formed of a copper foil or the like. The wiring board 110 may be a wiring board that is obtained by forming a conductor film on a surface of an insulating substrate that is formed of an inorganic material such as alumina or aluminum nitride. Further, the first semiconductor element 105 is also not particularly limited. Any semiconductor element, such as a microcomputer, a memory or an ASIC, can be used as the first semiconductor element 105. A material of the bump 111 is not particularly limited. Any conductive material can be used as the material of the bump 111. Preferably, a metal such as solder, gold or copper is used.

FIG. 5B illustrates an example in which a sealing resin 120 is filled between the printed wiring board 101 and the wiring board 110 of the semiconductor package 100 illustrated in FIG. 5A. In this way, by filling the sealing resin 120, the first semiconductor element 105 is protected from a mechanical stress. Further, expansion and contraction, warpage and the like of the printed wiring board 101 due to ambient temperature variation are limited. Thereby, a stress occurring in a portion connecting to the first semiconductor element 105 can be reduced. As a result, there is an advantage that reliability of the connection is improved. In the example illustrated in FIG. 5B, the sealing resin 120 is filled such that a space is left on the wiring board 110 side. However, the sealing resin 120 is preferably filled so as to at least cover the first semiconductor element 105. For example, it is possible that the sealing resin 120 is filled only in the cavity 5. Further, it is also possible that the sealing resin 120 is filled such that the interspace between the printed wiring board 101 and the wiring board 110 is completely filled. The sealing resin 120 can be filled so as to cover the first semiconductor element 105 at any thickness.

A material of the sealing resin 120 is not particularly limited. For example, a material is used having a thermal expansion coefficient close to that of the first semiconductor element 105 and/or that of the mold resin layer 10. Preferably, a thermosetting epoxy resin containing an appropriate amount of an inorganic filler such as SiO₂ is used. A method for filling the sealing resin 120 is not particularly limited. For example, it is possible that the sealing resin 120 is injected in a liquid state and thereafter is heated and cured.

FIG. 5C illustrates an example in which a second semiconductor element 115 is mounted on the wiring board 110 of the semiconductor package 100 illustrated in FIG. 5B. An electrode (not illustrated in the drawings) that is provided on a surface of the second semiconductor element 115 is connected to the wiring board 110 by a bonding wire 116. The second semiconductor element 115 may also be connected using a flip-chip mounting method. By using the semiconductor package illustrated in FIG. 5C, a compact and sophisticated semiconductor device can be provided.

Next, an example of a method for manufacturing the wiring board 1 of the present embodiment is described with reference to FIG. 6A-6N.

In the method for manufacturing the wiring board 1 of the present embodiment, first, as illustrated in FIG. 6A, as starting materials, a base plate 80 and a metal film (metal foil) 82 with a carrier copper foil 81 are prepared. The carrier copper foil 81 and the metal film 82 of the metal film with the carrier copper foil are bonded to each other, for example, by a thermoplastic adhesive (not illustrated in the drawings). The carrier copper foil 81 of the metal film with the carrier copper foil, for example, is pasted on the base plate 80 by thermal compression bonding, the base plate 80 being formed from a prepreg. The carrier copper foil 81 and the metal film 82 may also be bonded to each other only in a margin portion near an outer periphery. The base plate 80 has an appropriate rigidity. For example, the base plate 80 may be a metal plate of copper or the like, or may be an insulating plate of ceramics or the like. The metal film 82, for example, is a copper foil having a thickness of 1 μm or more and 6 μm or less.

FIG. 6A-6L illustrate an example of a manufacturing method in which the metal film 82 is bonded to each of both sides of the base plate 80, and the build-up wiring layer 11 and the like are formed on each of both sides of the base plate 80. However, it is also possible that the build-up wiring layer 11 and the like are formed on only one side of the base plate 80. Further, it is also possible that conductor layers and the like having mutually different circuit patterns are respectively formed on both sides of the base plate 80. In the following, description regarding the other side (80B) and reference numeral symbols for components on the other side (80B) are omitted.

As illustrated in FIG. 6B, a conductor pattern of the third conductor layer 60 is formed on the metal film 82. The conductor pattern of the third conductor layer 60 is formed in the following process. A resist pattern (not illustrated in the drawings) is formed having an opening at a position where the conductor pattern of the third conductor layer 60 is formed. The opening of the resist pattern is filled with a plating conductor by electroplating using the metal film 82 as a seed layer. By removing the resist pattern, the third conductor layer 60 having the predetermined conductor pattern is formed. The third conductor layer 60 is preferably formed to have a thickness of about 5 μm or more and 25 μm or less.

Next, as illustrated in FIG. 6C, the second resin insulating layer 50 is formed on the metal film 82 and on the third conductor layer 60. For example, a film-like insulating material is laminated on the third conductor layer 60, and is pressed and heated. Next, preferably, a CO₂ laser beam is irradiated to a predetermined place on a surface of the second resin insulating layer 50 on an opposite side of the third conductor layer 60 side. As illustrated in FIG. 6D, a conduction hole (55a) can be formed having a tapered shape that is gradually reduced in diameter toward the third conductor layer 60.

A metal layer 41 is formed, for example, by electroless plating in the conduction hole (55a) and on a surface of the second resin insulating layer 50. The metal layer 41 may also be formed by sputtering, vacuum deposition or the like.

A resist pattern (not illustrated in the drawings) having an opening at a predetermined position is formed on the metal layer 41. A plating film 42 is formed on a surface of the metal layer 41 by electroplating using the metal layer 41 as a seed layer. As illustrated in FIG. 6E, the second conductor layer 40 is formed by the metal layer 41 and the plating film 42 on the second resin insulating layer 50. Further, the via conductor 55 is formed by the metal layer 41 and the plating film 42 in the conduction hole (55a). The resist pattern is removed. An exposed portion of the metal layer 41 is removed by etching or the like. A material of the metal layer 41 and the plating film 42 is not particularly limited. However, copper is preferably used. The second conductor layer 40 is preferably formed to have a thickness of 5 μm or more and 25 μm or less.

Next, the resin insulating layer 30 is formed on the second conductor layer 40 and on the second resin insulating layer 50 using the same method as the method for forming the second resin insulating layer 50. The conductor layer 20 is formed on the resin insulating layer 30 using the same method as the method for forming the second conductor layer 40. The conductor layer 20 includes the first pad 21 and the second pad 22. The via conductor 35 that penetrates the resin insulating layer 30 is formed using the same method as the method for forming the via conductor 55 (FIG. 6F).

As illustrated in FIG. 6G, the dummy member 7 is positioned in a formation area of the cavity 5. The dummy member 7, for example, is a resin film that is formed to have a size and a shape that are substantially the same as the formation area of the cavity 5. For example, a film can be used that can be in close contact with the first pad 21 and the resin insulating layer 30 but cannot be firmly bonded to the first pad 21 and the resin insulating layer 30. For example, as illustrated in FIG. 6G, the dummy member 7 may be bonded to the first pad 21 and the resin insulating layer 30 using an adhesive 8. As the dummy member 7 and the adhesive 8, materials that do not bond to the mold resin layer 10 are preferred. The dummy member 7, for example, is formed from a resin material such as a polyimide. An adhesive having a degree of adhesiveness that allows the adhesive to be peeled from the first pad 21 and the resin insulating layer 30 is used as the adhesive 8. The depth of the cavity can be easily adjusted by suitably selecting a thickness of the dummy member 7 and/or a thickness of the adhesive 8.

Next, the mold resin layer 10 is formed so as to cover the dummy member 7 (FIG. 6H). A mold resin, for example, can be supplied in a liquid or paste form by discharging the mold resin from a nozzle. It is also possible that a film-like mold resin is laminated on the dummy member 7 and is heated. The dummy member 7, the resin insulating layer 30 and the like can be covered by the mold resin that is softened by heating. The mold resin layer 10 is formed such that the surface of the mold resin layer 10 is positioned above one surface (7F) of the dummy member 7. The mold resin layer 10 is formed to have a thickness of, for example, 30 μm or more and 150 μm or less.

As illustrated in FIG. 6I, the opening (14a) that penetrates the mold resin layer 10 is formed. The opening (14a) is formed so as to expose a portion of the second pad 22. After the opening (14a) is formed, in order to remove attached resin residues, preferably, the inner wall surface of the opening (14a) is subjected to a desmear treatment by immersing the opening (14a) in a permanganate solution or the like. By adjusting a processing time of using the permanganate solution or the like in the desmear treatment, the surface roughness of the inner wall surface of the opening (14a) can be adjusted. Adhesion between the conductor post 14 and the wall surface of the opening (14a) can be improved. In the desmear treatment, the surface of the mold resin layer 10 may also be roughened.

As illustrated in FIG. 6J, the electroless plating film 26 is formed on the inner wall surface of the opening (14a). The electrolytic plating film 27 is formed using the electroless plating film 26 as a seed layer (FIG. 6K). The opening (14a) is filled by the electroless plating film 26 and the electrolytic plating film 27, and the conductor post 14 is formed. A conductor film 17 is also formed on the surface of the mold resin layer 10.

As illustrated in FIG. 6L, the surface side of the mold resin layer 10 is polished such that the one surface (7F) of the dummy member 7 is exposed from the mold resin layer 10. Preferably, the polishing of the mold resin layer 10 is terminated when the one surface (7F) of the dummy member 7 is exposed. The depth of the cavity 5 becomes substantially equal to the thickness of the dummy member 7. Further, in order to form a cavity 5 of a desired depth, it is also possible that a portion of the dummy member 7 on the one surface (7F) side and the mold resin layer 10 are polished until the thickness of the dummy member 7 is equal to the desired depth of the cavity 5. For example, sandblasting, buffing, chemical mechanical polishing (CMP) or the like is used for the polishing of the mold resin layer 10. However, the polishing method is not limited to these methods.

Thereafter, as illustrated in FIG. 6M, the base plate 80 and the carrier copper foil 81 are removed. As described above, the carrier copper foil 81 and the metal film 82 are bonded to each other by a thermoplastic resin. Therefore, for example, by raising temperature and applying a force, the base plate 80 and the carrier copper foil 81 can be easily separated from the metal film 82. As a result, the bonding surface of the metal film 82 to the carrier copper foil 81 is exposed. When the carrier copper foil 81 and the metal film 82 are bonded to each other only in a peripheral margin portion, the two can be easily separated by cutting an inner side of the bonded portion. FIG. 6M illustrates the printed wiring board on the upper surface side of the base plate 80 in FIG. 6L.

The dummy member 7 is removed from the halfway-processed printed wiring board. For example, a tool sucks on the one surface (7F) of the dummy member 7 and the dummy member 7 is pulled up. When the adhesive 8 is used, preferably, together with the dummy member 7, the adhesive 8 is also removed. It is also possible that the dummy member 7 and the adhesive 8 are removed by a solvent or the like. As illustrated in FIG. 6N, the cavity 5, which is surrounded by the mold resin layer 10, is formed.

The metal film 82 is removed by etching or the like. When the same material as the metal film 82 is used for the conductor post 14 and the first pad 21, the end surface (14b) of the conductor post 14 and an exposed surface (21a) of the first pad 21 are also etched at the same time. As a result, as in the printed wiring board 1 illustrated in FIG. 1, the end surface (14b) of the conductor post 14 may be recessed from the surface of the mold resin layer 10. The printed wiring board 1 illustrated in FIG. 1 is completed. When necessary, a solder resist (not illustrated in the drawings) may be applied to the back surface side of the printed wiring board 1 (the second surface (11B) side of the build-up wiring layer 11).

The end surface (14b) of the conductor post 14 can be roughened by the etching when the metal film 82 is removed. The surface roughness of the inner wall surface of the opening (14a) in the mold resin layer 10 can be adjusted by the above-described desmear treatment. The conductor post 14 may have different surface roughnesses on its end surface (14b) and on its side surface that is in contact with the mold resin layer 10.

Further, a printed wiring board having a build-up wiring layer that is formed by laminating less then or more than two conductor layers and two resin insulating layers can be formed by adjusting the number of repetitions of the processes illustrated in FIG. 6C-6E.

The printed wiring board illustrated in FIG. 4 can be manufactured by repeating the processes described with reference to FIG. 6G-6L. That is, after the one surface (7F) of the dummy member 7 is exposed by polishing the mold resin layer 10, the processes illustrated in FIG. 6G-6L are repeated. A second dummy member (not illustrated in the drawings) is positioned directly or via an adhesive on the one surface (7F) of the dummy member 7. A second mold resin layer (10a) is formed to cover the second dummy member, and an opening (142a) is formed using a laser beams. The opening (142a) is formed such that a portion of the end surface (141b) of the first conductor post 141 is exposed on a bottom surface. By filling the opening (142a) with an electroless plating film 261 and an electrolytic plating film 271, the second conductor post 142 is formed. Then, the second mold resin layer (10a) is polished such that one surface of the second dummy member is exposed. The conductor post 14 is formed having a laminated structure that includes the first conductor post 141 and the second conductor post 142 that is firmly bonded to the end surface (141b) of the first conductor post 141. The dummy member 7 and the second dummy member are removed collectively or one at a time as described above before the removal of the metal film 82. By further repeating the processes illustrated in FIG. 6G-6L, a conductor post having a laminated structure of three or more layers can be formed. A printed wiring board can be manufactured having a deep cavity capable of accommodating a relatively thick electronic component, and having a conductor post of a desired height capable of connecting to another wiring board positioned above the cavity.

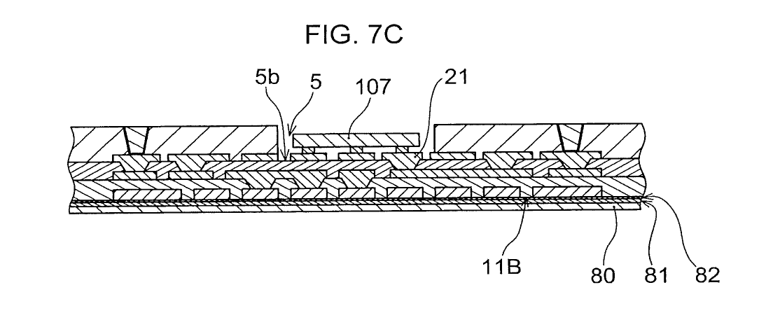

FIG. 7A further illustrates another embodiment, which a modified embodiment of the printed wiring board 1 illustrated in FIG. 1. In the printed wiring board (1b), a base plate 80 is provided on the second surface (11B) side of the build-up wiring layer 11 of the printed wiring board 1 illustrated in the above-described FIG. 1. Deflection or bending of the printed wiring board (1b) is prevented. This facilitates handling of the printed wiring board (1b). A metal film (metal foil) 82 with a carrier copper foil 81 is provided between the base plate 80 and the second surface (11B) of the build-up wiring layer 11.

Such a printed wiring board (1b), for example, as illustrated in FIG. 7B, can be formed by using a base plate (80b) that is formed by superimposing two prepregs and bonding the two prepregs to each other using an easily peelable adhesive 83. By peeling the adhesive 83 portion, two printed wiring boards (1b) are obtained each having a base plate 80. Such a printed wiring board (1b) is manufactured using the same method as the above-described example of the manufacturing method illustrated in FIG. 6A-6N until the process of FIG. 6L. The base plate (80b) illustrated in FIG. 7B is used from the initial process (FIG. 6A). FIG. 7B illustrates a process subsequent to the above-described process of FIG. 6L. That is, in the method (FIG. 6A-6N) for manufacturing the printed wiring board 1 illustrated in FIG. 1, the base plate 80 is removed in the process illustrated in FIG. 6M. However, in the processes for manufacturing the printed wiring board (1b), without removing the base plate (80b), the dummy member 7 is removed from the halfway-processed printed wiring board. The build-up wiring layer 11 is stable due to the base plate (80b) and thus can be very easily handled. Thereafter, the adhesive 83 is peeled.

As illustrated in FIG. 7C, an electronic component 107 can be positioned in the cavity 5 of the printed wiring board (1b). An electrode of the electronic component 107 is connected to the first pad 21 that is exposed on the bottom surface (5b) of the cavity 5 of the printed wiring board (1b). Due to the rigidity of the base plate 80, the process of mounting the electronic component in the cavity 5 can become easy.

In an electronic component package, an upper package and a lower package may be connected to each other by using a solder ball (connection terminal for lamination). However, it is likely that positioning solder balls at a fine pitch is relatively difficult, and that forming a good quality electronic component package of a package-on-package structure having connection pads formed at a fine pitch is difficult.

A printed wiring board according to an embodiment of the present invention includes: a build-up wiring layer that is formed by alternately laminating a resin insulating layer and a conductor layer and has a first surface and a second surface that is on an opposite side of the first surface; a first pad that connects to an electronic component and a second pad that connects to an external wiring board, the first pad and the second pad being formed on the first surface of the build-up wiring layer; a mold resin layer that covers the first surface of the build-up wiring layer and has a cavity that exposes the entire first pad and an opening that exposes a portion of the second pad; and a conductor post that is formed from a plating layer in the opening of the mold resin layer so as to be connected to the second pad. The conductor post is formed from an electroless plating layer and an electrolytic plating layer. An end surface of the conductor post on an opposite side of the second pad side is exposed from a surface of the mold resin layer.

A semiconductor package according to an embodiment of the present invention includes a printed wiring board on which a first semiconductor element is mounted, and includes an external wiring board that is mounted on one surface of the printed wiring board. The printed wiring board includes: a build-up wiring layer that is formed by alternately laminating a resin insulating layer and a conductor layer and has a first surface and a second surface that is on an opposite side of the first surface; a first pad that connects to an electronic component and a second pad that connects to an external wiring board, the first pad and the second pad being formed on the first surface of the build-up wiring layer; a mold resin layer that covers the first surface of the build-up wiring layer and has a cavity that exposes the first pad and an opening that exposes a portion of the second pad; and a conductor post that is formed from a plating layer in the opening of the mold resin layer so as to be connected to the second pad. An end surface of the conductor post on an opposite side of the second pad side is exposed from a surface of the mold resin layer. The conductor post is formed from an electroless plating layer and an electrolytic plating layer, and has a tapered shape that is gradually reduced in diameter toward the second pad. The wiring board has a bump on a surface on the printed wiring board side. The bump is connected to the build-up wiring layer via the conductor post and the second pad.

According to an embodiment of the present invention, terminals (conductor posts) connecting to an external wiring board can be formed at a fine pitch. Further, according to the embodiment of the present invention, reliability of connection to an external wiring board can be improved.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a build-up wiring layer comprising a resin insulating layer and a conductor layer;
a plurality of pads formed on a first surface of the build-up wiring layer and comprising a plurality of first pads and a plurality of second pads such that the first pads are positioned to connect an electronic component onto the first surface of the build-up wiring layer and the second pads are positioned to connect an external wiring board onto the first surface of the build-up wiring layer;
a mold resin layer formed on the first surface of the build-up wiring layer such that the mold resin layer is covering the first surface of the build-up wiring layer and has a cavity portion exposing the plurality of first pads and a plurality of opening portions exposing the plurality of second pads, respectively; and
a plurality of conductor posts formed in the plurality of opening portions of the mold resin layer respectively and comprising plating material such that the plurality of conductor posts is connected to the plurality of second pads, respectively,
wherein the plating material of the plurality of conductor posts comprises an electroless plating layer and an electrolytic plating layer, and the plurality of conductor posts is formed such that each of the conductor posts has an end surface exposed from a surface of the mold resin layer on an opposite side with respect to the second pads.

2. A printed wiring board according to claim 1, wherein the plurality of conductor posts is formed such that each of the conductor posts has a tapered form decreasing a diameter toward a respective one of the second pads.

3. A printed wiring board according to claim 1, wherein the plurality of conductor posts is formed such that each of the conductor posts has the end surface which is on a same plane with the surface of the mold resin layer or recessed from the surface of the mold resin layer.

4. A printed wiring board according to claim 1, wherein the plurality of pads is formed such that a pitch of the first pads is smaller than a pitch of the second pads.

5. A printed wiring board according to claim 1, wherein the plurality of conductor posts is formed such that the end surface has a surface roughness which is smaller than a surface roughness of a side surface in contact with the mold resin layer.

6. A printed wiring board according to claim 1, wherein the mold resin layer comprises a resin material comprising resin and an inorganic filler such that the inorganic filler is in a range of 60% by mass to 95% by mass.

7. A printed wiring board according to claim 6, wherein the inorganic filler comprises SiO₂.

8. A printed wiring board according to claim 1, further comprising:
a base plate positioned on a second surface of the build-up wiring layer on an opposite side with respect to the first surface.

9. A printed wiring board according to claim 8, wherein the base plate comprises one of a prepreg material and a metal plate.

10. A printed wiring board according to claim 2, wherein the plurality of conductor posts is formed such that each of the conductor posts has the end surface which is on a same plane with the surface of the mold resin layer or recessed from the surface of the mold resin layer.

11. A printed wiring board according to claim 2, wherein the plurality of pads is formed such that a pitch of the first pads is smaller than a pitch of the second pads.

12. A printed wiring board according to claim 2, wherein the plurality of conductor posts is formed such that the end surface has a surface roughness which is smaller than a surface roughness of a side surface in contact with the mold resin layer.

13. A printed wiring board according to claim 2, wherein the mold resin layer comprises a resin material comprising resin and an inorganic filler such that the inorganic filler is in a range of 60% by mass to 95% by mass.

14. A printed wiring board according to claim 2, further comprising:
a base plate positioned on a second surface of the build-up wiring layer on an opposite side with respect to the first surface.

15. A semiconductor package, comprising:
a printed wiring board;
a first semiconductor element mounted on the printed wiring board; and
an external wiring board mounted on the printed wiring board,
wherein the printed wiring board comprises a build-up wiring layer comprising a resin insulating layer and a conductor layer, a plurality of pads formed on a first surface of the build-up wiring layer and comprising a plurality of first pads and a plurality of second pads such that the first pads are positioned to connect the electronic component onto the first surface of the build-up wiring layer and the second pads are positioned to connect the external wiring board onto the surface of the build-up wiring layer, a mold resin layer formed on the first surface of the build-up wiring layer such that the mold resin layer is covering the first surface of the build-up wiring layer and has a cavity portion exposing the plurality of first pads and a plurality of opening portions exposing the plurality of second pads, respectively, and a plurality of conductor posts formed in the plurality of opening portions of the mold resin layer respectively and comprising plating material such that the plurality of conductor posts is connected to the plurality of second pads, respectively, the plating material of the plurality of conductor posts comprises an electroless plating layer and an electrolytic plating layer, the plurality of conductor posts is formed such that each of the conductor posts has an end surface exposed from a surface of the mold resin layer on an opposite side with respect to the second pads and that each of the conductor posts has a tapered form decreasing a diameter toward a respective one of the second pads, and the external wiring board has a plurality of bumps positioned to connect to the plurality of conductor posts respectively such that the external wiring board is electrically connected to the build-up wiring layer of the printed wiring board.

16. A semiconductor package according to claim 15, further comprising:
a sealing resin filling a space formed between the printed wiring board and the external wiring board such that the first semiconductor element is positioned in the cavity portion of the mold resin layer.

17. A semiconductor package according to claim 15, further comprising:
a second semiconductor element mount on the external wiring board.

18. A method for manufacturing a printed wiring board, comprising:
forming, on a surface of a resin insulating layer, a plurality of pads comprising a plurality of first pads and a plurality of second pads such that the first pads are positioned to connect an electronic component onto the surface of the resin insulating layer and the second pads are positioned to connect an external wiring board onto the surface of the resin insulating layer;
forming, on the plurality of first pads, a dummy member having a shape corresponding to a cavity portion, such that the dummy member covers the plurality of first pads;
applying mold resin onto the surface of the resin insulating layer such that the mold resin covers the surface of the resin insulating layer and the dummy member formed on the plurality of first pads;
polishing the mold resin applied onto the surface of the resin insulating layer such that a surface of the dummy member is exposed; and
removing the dummy member from the resin insulating layer such that a mold resin layer having the cavity portion is formed on the surface of the resin insulating layer to expose the plurality of first pads in the cavity portion of the mold resin layer.

19. A method for manufacturing a printed wiring board according to claim 18, further comprising:
forming a plurality of penetrating holes through the mold resin layer prior to the polishing such that the plurality of penetrating holes exposes the plurality of second pads, respectively; and
applying plating such that the plurality of penetrating holes is filled with plating material forming a plurality of conductor bodies filling the plurality of penetrating holes, respectively.

20. A method for manufacturing a printed wiring board according to claim 19, further comprising:
etching a metal film formed on a surface of the mold resin layer prior to the removing of the dummy member such that each of the conductor bodies has an end surface recessed from the surface of the mold resin layer,
wherein the resin insulating layer is forming an outmost layer of a build-up wiring layer comprising the resin insulating layer and a conductor layer.
